(19) United States
(12) Patent Application Publication
(10) Pub. No.: US 2006/0245150 A1
(43) Pub. Date: Nov. 2, 2006

(54) Interconnect Cartridge

(76) Inventor: Tingbao Chen, Cupertino, CA (US)

Correspondence Address: Tingbao Chen, 10193 Park Circle East, #3, Cupertino, CA, 95014, US

(21) Appl. No.: 11/379,830

(22) Filed: Apr. 24, 2006

Related U.S. Application Data
(60) Provisional application No. 60/594,699, filed on Apr. 29, 2005.

(51) Int. Cl. H05K 5/00

(52) U.S. Cl. 361/679

(57) ABSTRACT

The current existing interconnect technologies, for example, spring probes, bent metals, fuzz buttons, etc. have the characteristics that combine the two major functions of electrical connectivity and mechanical compliance into one component. That makes it extremely difficult to improve electrical performance without sacrificing the mechanical compliance, or vice versa, especially when the pitch of the contact array becomes smaller and smaller as well as the signal speed of the electronics devices becomes higher and higher. The present invention separates the above mentioned two major functions of electrical connectivity and mechanical compliance from one component and integrates these functions into one interconnect cartridge. The present invention makes it possible to enhance both electrical performance and mechanical compliance at the same time.

### RELATED APPLICATIONS

The present application is a continuation-in-part application of U.S. provisional patent application, Ser. No. 60/594699, filed Apr. 29, 2005, for UNCONVENTIONAL INTERCONNECT CONTACTOR CARTRIDGE, by Tingbao Chen, included by reference herein and for which benefit of the priority date is hereby claimed.

This application is based upon prior filed provisional application Ser. No. 60/594,699 filed Apr. 29, 2005, the entire subject matter of which is incorporated herein by reference in its entirety.

### FIELD OF THE INVENTION

The present invention relates to electrical interconnect devices and, more particularly, to electrical interconnect cartridges that provide electrical connectivity and mechanical compliance independently to electronics devices.

### BACKGROUND OF THE INVENTION

The current existing interconnect technologies, for example, spring probes, bent metals, fuzz buttons, just to name a few, all have the characteristics that combine two major functions of electrical connectivity and mechanical compliance into one unit. That makes it extremely difficult to improve electrical performance, such as lower resistance and inductance, without sacrificing mechanical compliance, or vice versa, especially when the pitch (center-to-center distance) of the application contact array becomes smaller and smaller as well as the signal speed of the electronics devices becomes higher and higher. It is always a tough balance between the fore said two functions because, within one unit, these two functions are often conflicting to each other.

The present Invention employs the concept that separates the above mentioned two functions and maintains the interconnect cartridge as a whole unit.

An interconnect cartridge is a mechanism comprising a housing, an array of interconnects, springs, and necessary guides and fasteners. The housing consists of two support plates of dielectric materials to provide support to the interconnects and the springs. The interconnects comprise bulk connectors of conductive wires and contact probes to provide electrical connectivity to electronics devices. The bulk connectors of conductive wires can be compressed or extended when the interconnect cartridge is compressed or released. The springs provide the desired contact force to the contact probes and mechanical compliance to the interconnect cartridge.

The current existing interconnect technologies, such as spring probes, bent metals, fuzz buttons, and so on, inherent the characteristics that combines electrical connectivity and mechanical compliance into one unit. Because the electrical performance and the mechanical compliance are conflicting to each other, it is difficult to have them both enhanced at the same time.

The current existing interconnect technologies have an inherent obstacle for improving both electrical connectivity performance and mechanical compliance at the same time, due to the conflicting nature of these two functions within one unit. No current approach explores the possibility to separate the said two functions from the interconnect component so that they are no longer conflicting functions and both can be improved at the same time.

It is an object of the invention to provide an interconnect cartridge.

It is an object of the invention of the interconnect cartridge that provides electrical connectivity and mechanical compliance independently.

It is an object of the invention to provide electrical connectivity and mechanical compliance independently so that these two functions can be improved at the same time.

### SUMMARY OF THE INVENTION

In accordance with the present invention, there is provided an interconnect cartridge that comprises a housing, an array of interconnects and springs to provide electrical connectivity and mechanical compliance to application electronics devices. The housing consists of two support plates of dielectric materials to provide support to the interconnects and the springs. The springs provide the desired contact force to the contact probes and mechanical compliance to the interconnect cartridge. The interconnects consist of bulk connectors and contact probes. The said bulk connectors comprise coiled, electrically conductive wires and each said bulk connector has two, four, or any even number of wires coiled in opposite direction, i.e. clockwise and counter-clockwise. At the ends of the coiled wires are two contact probes making contacts to the application devices. The said contact probes may be any size and form such as crown tips, cone tips, or balls. The springs which provide desired contact force and mechanical compliance may be any size and form that has spring property of mechanical deflection and force. Since the electrical connectivity and mechanical compliance are provided by separate mechanisms, both functions are independent and can be improved at the same time without sacrificing each other.

### BRIEF DESCRIPTION OF THE DRAWINGS

A complete understanding of the present invention may be obtained by reference to the accompanying drawings, when considered in conjunction with the subsequent, detailed description, in which:

FIG. 1 is a perspective view of an interconnect cartridge;

FIG. 2 is a top view of an interconnect cartridge;

FIG. 3 is a section view of an interconnect cartridge;

FIG. 4 is a detail view of an interconnect components;

FIG. 5 is a front sectional view of an interconnect cartridge with application electronics devices;

FIG. 6 is a front view of an alternate bulk connector; and

FIG. 7 is a front view of another alternate bulk connector.

FIG. 8 is a front view of another further alternate bulk connector.

For purposes of clarity and brevity, like elements and components will bear the same designations and numbering throughout the Figures.

### DESCRIPTION OF THE PREFERRED EMBODIMENT

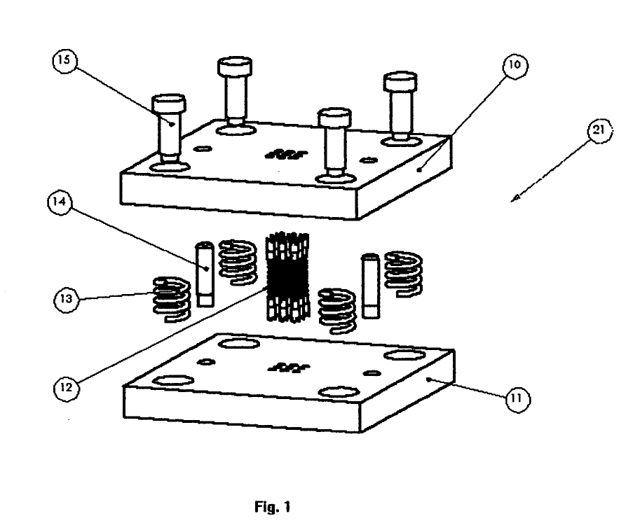

FIG. 1 is a perspective view of an exploded interconnect cartridge 21, in accordance with the invention. The number of interconnects 12 and the number of springs 13 are for illustration only. The said number of interconnects 12 and the said number of springs 13 are subject to specific application requirements.

The housing consists of two dielectric support plates: support plate top 10 and support plate bottom 11. The material of the said support plates may be any suitable dielectric materials such as PCB material, dielectric plastics, and so on. The support plate top 10 and support plate bottom 11 may be any size and form depending on specific application, and may be fabricated by machining, molding, or any other suitable fabrication processes. The contact probes are attached to support plate top 10 and support plate bottom 11 as well as the bulk connectors 16. Support plate top 10 and the contact probes attached to it can move along the guides 14 when they are compressed and released by the application devices.

The contact probe top 18 and contact probe bottom 17 are attached to support plate top 10 and support plate bottom 11. The attachment may be press fit, soldering, or any other suitable means available. The contact probe top 18 and contact probe bottom 17 are attached directly to the bulk connectors 16 to form the interconnects 12. The contact probe top 18 and contact probe bottom 17 may be any size and form, such as crown tips, cone tips or balls, depending on specific application. The bulk connectors 16 are formed by two conductive wires coiled in opposite direction, i.e. clockwise and counter-clockwise. The conductive wires are coiled such that they are extendable and compressible under force.

The support plate top 10 and support plate bottom 11 are fastened together with a designated gap by special fasteners 15. The fasteners 15 may also be features built in the support plates. The gap provides the capability for the support plate top 10 to move along the guides 14 such that provides the mechanical compliance of the interconnect cartridge 21. The gap can be designed in such a way to meet specific application requirement. The guides 14 provide the desired precision alignment between support plate top 10 and support plate bottom 11.

The springs 13 provide the desired contact force among the contact probes and the application electronics device bottom 19 and electronics device top 20. The said springs 13 also provide the support plate top 10 with spring force so that the said support plate top 10 will return to its original position when the electronics device top 20 is removed. The number of springs 13 are subject to specific application

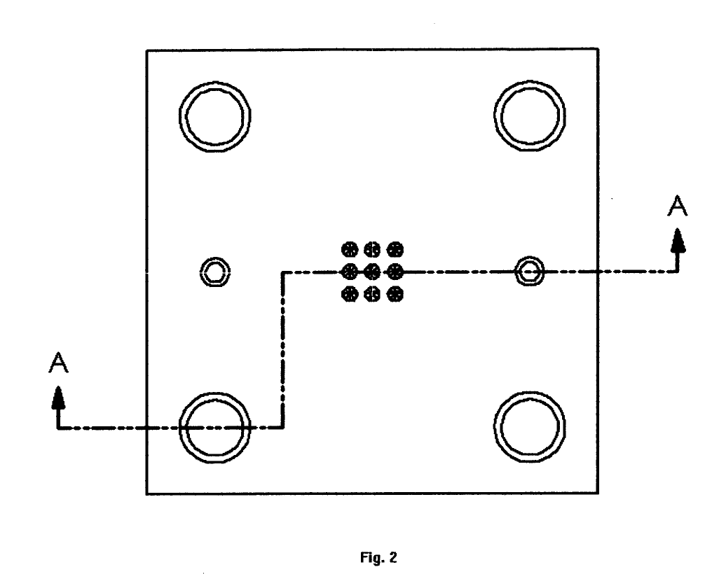

FIG. 2 is a top view of the interconnect cartridge 21.

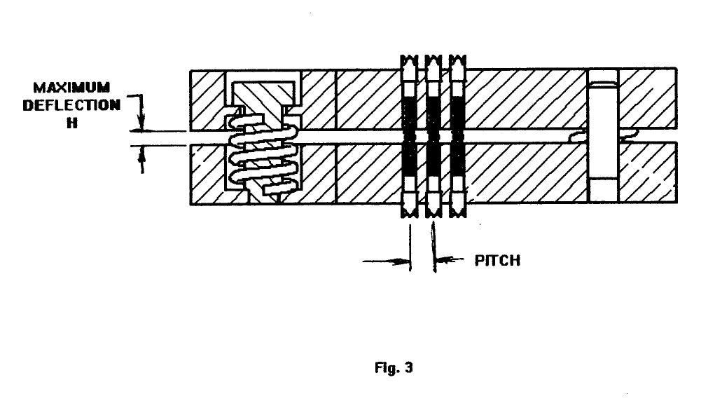

FIG. 3 is a front sectional view of the interconnect cartridge 21.

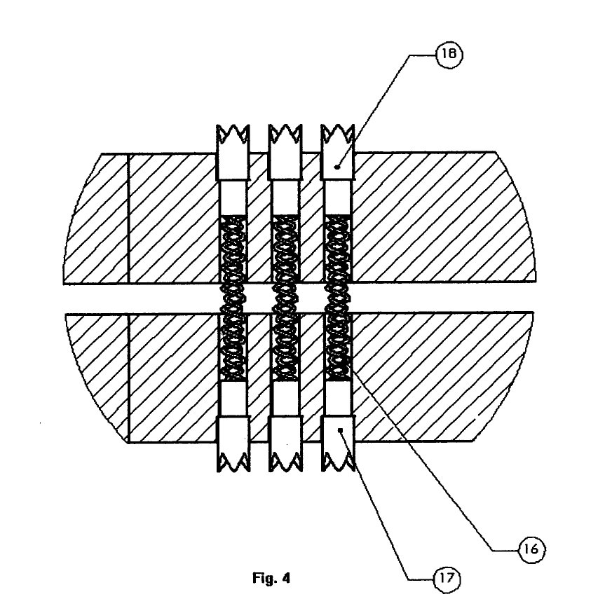

FIG. 4 is a detail view of the interconnects 12.

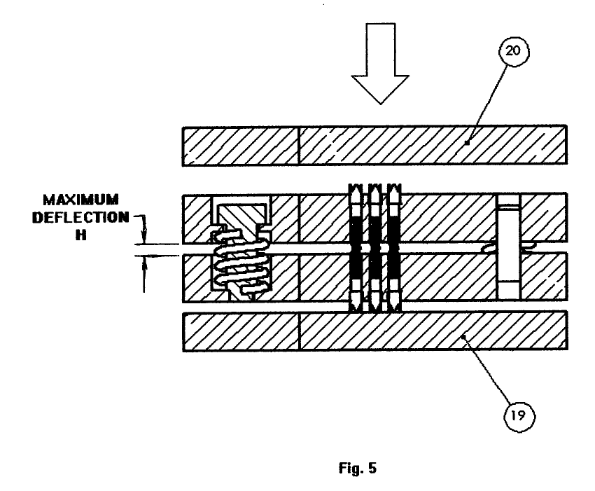

FIG. 5 is a front sectional view of the interconnect cartridge 21 with application electronics devices. The interconnect cartridge 21 sits on electronics device bottom 19. When electronics device top 20 is pushed down, the interconnects 12 are compressed together with support plate top 10 to make electrical connections between electronics device bottom 19 and electronics device top 20. When the electronics device top 20 is removed, the interconnects 12 and support plate top 10 will be sprung back to their initial position by the springs 13.

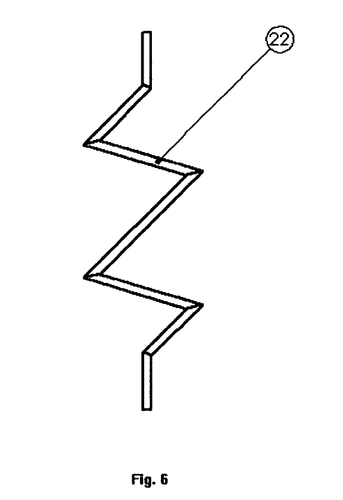

FIG. 6 is a front view of an alternate bulk connector 22. It is formed by a single conductive wire in zigzag shape.

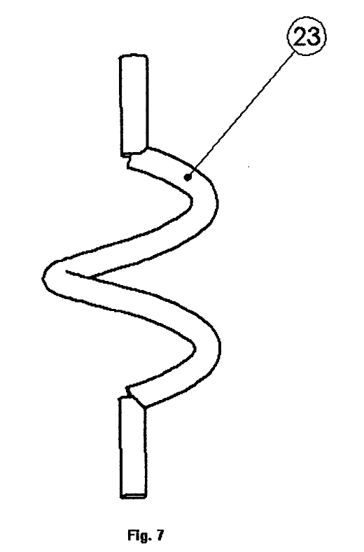

FIG. 7 is a front view of another alternate bulk connector 23. It is a short, coiled, single conductive wire.

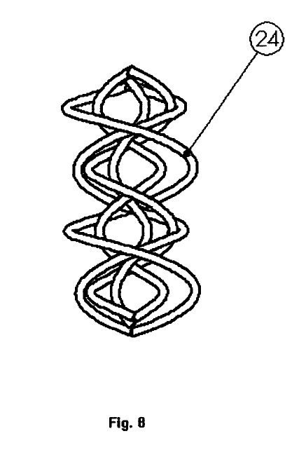

FIG. 8 is a front view of another further alternate bulk connector 24. It is formed by multiple (three and more) wires coiled in opposite directions.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. An interconnect cartridge for providing electrical connectivity and mechanical compliance between electronics devices, comprising:
means for providing supporting structure for the interconnects and springs;
means for providing electrical connectivity between contact probes with flexibility so that it can be compressed and extended under force;
means for providing desired contact force and mechanical compliance to the interconnect cartridge so that the said interconnect cartridge can be compressed under force and return to its original position when the said force is removed, adjacently coupled to said means for providing supporting structure for the interconnects and springs;
means for providing electrical connectivity between bulk connectors and external electronics devices, rigidly connected to said means for providing electrical connectivity between contact probes with flexibility so that it can be compressed and extended under force, and rigidly connected to said means for providing supporting structure for the interconnects and springs;
means for providing attachment between support plate top and support plate bottom, rigidly connected to said means for providing supporting structure for the interconnects and springs; and
means for providing electrical connectivity between contact probes with flexibility so that it can be compressed and extended under force.

2. The interconnect cartridge in accordance with claim 1, wherein said means for providing supporting structure for the interconnects and springs comprises a dielectric support plate top, being fabricated with an array of isolated cavities by any suitable fabrication processes such as machining, molding.

3. The interconnect cartridge in accordance with claim 1, wherein said means for providing supporting structure for the interconnects and springs comprises a dielectric support plate bottom, being fabricated with an array of isolated cavities by any suitable fabrication processes such as machining, molding.

4. The interconnect cartridge in accordance with claim 1, wherein said means for providing electrical connectivity between contact probes with flexibility so that it can be compressed and extended under force comprises two conductive, flexible, any size, and any form wires being coiled in opposite direction, namely clockwise and counter-clockwise bulk connectors.

5. The interconnect cartridge in accordance with claim 1, wherein said means for providing desired contact force and mechanical compliance to the interconnect cartridge so that the said interconnect cartridge can be compressed under force and return to its original position when the said force is removed comprises a compressible, any size, any form, and any shape springs.

6. The interconnect cartridge in accordance with claim 1, wherein said means for providing electrical connectivity between bulk connectors and external electronics devices comprises a conductive, rigid contact probe top, being fabricated in any size, form and shape such as crown tips, cone tips, balls.

7. The interconnect cartridge in accordance with claim 1, wherein said means for providing electrical connectivity between bulk connectors and external electronics devices comprises a conductive, rigid contact probe bottom, being fabricated in any size, form, and shape such as crown tips, cone tips, balls.

8. The interconnect cartridge in accordance with claim 1, wherein said means for providing attachment between support plate top and support plate bottom comprises a connection of one of the following group of features, individual fasteners, features built in the housing.

9. The interconnect cartridge in accordance with claim 1, wherein said means for providing electrical connectivity between contact probes with flexibility so that it can be compressed and extended under force comprises a conductive, zigzag shaped wire alternate bulk connector.

10. The interconnect cartridge in accordance with claim 1, wherein said means for providing electrical connectivity between contact probes with flexibility so that it can be compressed and extended under force comprises a conductive, single coiled wire alternate bulk connector.

11. The interconnect cartridge in accordance with claim 1, wherein said means for providing electrical connectivity between contact probes with flexibility so that it can be compressed and extended under force comprises conductive, multiple wires coiled in opposite directions namely clockwise and counter-clockwise alternate bulk connector.

12. An interconnect cartridge for providing electrical connectivity and mechanical compliance between electronics devices, comprising:
a dielectric support plate top, being fabricated with an array of isolated cavities by any suitable fabrication processes such as machining, molding, for providing supporting structure for the interconnects and springs;
a dielectric support plate bottom, being fabricated with an array of isolated cavities by any suitable fabrication processes such as machining, molding, for providing supporting structure for the interconnects and springs;
conductive, flexible, any size, any form, two wires being coiled in opposite direction, namely clockwise and counter-clockwise bulk connectors, for providing electrical connectivity between contact probes with flexibility so that it can be compressed and extended under force;
compressible, any size, any form, any shape springs, for providing desired contact force and mechanical compliance to the interconnect cartridge so that the said interconnect cartridge can be compressed under force and return to its original position when the said force is removed, adjacently coupled to said support plate bottom, and adjacently coupled to said support plate top;
a conductive, rigid contact probe top, being fabricated in any size, form and shape such as crown tips, cone tips, balls, for providing electrical connectivity between bulk connectors and external electronics devices, rigidly connected to said bulk connectors, and rigidly connected to said support plate top;
a conductive, rigid contact probe bottom, being fabricated in any size, form, and shape such as crown tips, cone tips, balls, for providing electrical connectivity between bulk connectors and external electronics devices, rigidly connected to said bulk connectors, and rigidly connected to said support plate bottom;
a connection, comprising one the following group of features, individual fasteners, features built in the housing, for providing connection between support plate top and support plate bottom, rigidly connected to said support plate bottom, and relatively coupled to said support plate top;
a conductive, zigzag shaped single wire alternate bulk connector, for providing electrical connectivity between contact probes with flexibility so that it can be compressed and extended under force;
a conductive, coiled single wire alternate bulk connector, for providing electrical connectivity between contact probes with flexibility so that it can be compressed and extended under force; and
a conductive, multiple wires coiled in opposite directions namely clockwise and counter-clockwise alternate bulk connector, for providing electrical connectivity between contact probes with flexibility so that it can be compressed and extended under force.

13. The interconnect cartridge as recited in claim 12, further comprising:
an alignment feature, for providing precision guide to support plate top and support plate bottom so that the said support plate top and support plate bottom can move precisely when they are compressed and released, coaxially engaged to said support plate top, and rigidly connected to said support plate bottom.
